(19) United States
(12) Patent Application Publication
(10) Pub. No.: US 2022/0255036 A1
(43) Pub. Date: Aug. 11, 2022

(54) DISPLAY PANEL AND MANUFACTURING METHOD THEREOF, AND DISPLAY DEVICE

(71) Applicants: Hefei Xinsheng Optoelectronics Technology Co., Ltd., Hefei, Anhui, (CN); BOE TECHNOLOGY GROUP CO., LTD., Beijing (CN)

(72) Inventor: Leilei CHENG, Beijing (CN)

(21) Appl. No.: 17/630,666

(22) PCT Filed: Apr. 20, 2021
(86) PCT No.: PCT/CN2021/088251

§ 371 Date: Jan. 27, 2022

(30) Foreign Application Priority Data
Apr. 26, 2020 (CN) 202010338397.0

(51) Int. Cl. H01L 51/52; H01L 51/56

(52) U.S. Cl. CPC H01L 51/5218; H01L 51/56; H01L 2251/305; H01L 51/5228; H01L 51/5284; H01L 51/5212

(57) ABSTRACT

A display panel includes: a plurality of pixel units on a side of a substrate, with each pixel unit including a light emitting device which includes a first electrode, a light emitting layer and a second electrode in sequence on the side of the substrate; and an auxiliary electrode layer on a side of the pixel units distal to the substrate and including light-transmitting regions and electrode regions, with an orthogonal projection of a corresponding light-transmitting region on the substrate at least covering that of the light emitting layer on the substrate, each light-transmitting region including a transparent structure, each electrode region including an auxiliary electrode, and the auxiliary electrode being electrically connected to the second electrode. A material of the auxiliary electrode includes a metal. A material of the transparent structure includes a metal oxide. The metal oxide and the metal have a same kind of element.

### CROSS-REFERENCE TO RELATED APPLICATIONS

The present disclosure claims the priority to Chinese Patent Application No. 202010338397.0 filed on Apr. 26, 2020, the entire contents of which are incorporated herein by reference.

### TECHNICAL FIELD

The present disclosure belongs to the field of display technology, and particularly relates to a display panel and a manufacturing method thereof, and a display device.

### BACKGROUND

An Organic Light-Emitting Diode (OLED) display panel includes a plurality of pixel units, each of which is provided therein with a light emitting device (i.e., an OLED). The light emitting device may include an anode, a light emitting layer, and a cathode, and a light-emitting side of the light emitting layer is proximal to the cathode. In order to improve light extraction efficiency of the OLED (i.e., the light emitting device), a thickness of the cathode of the light emitting device needs to be as small as possible. However, as the thickness of the cathode decreases, a resistivity of the cathode increases (and thus power consumption of the OLED increases). In order to reduce an impedance of the cathode to reduce the power consumption of the OLED, the cathode of the light emitting device needs to be connected to an auxiliary electrode. Therefore, a suitable manufacturing method and a suitable configuration method of the auxiliary electrode are expected to improve the light extraction efficiency of the light emitting device and display quality of the display panel.

### SUMMARY

Some embodiments of the present disclosure provide a display panel and a manufacturing method thereof, and a display device.

In a first aspect of the present disclosure, there is provided a display panel, including:

a substrate;

a plurality of pixel units on a side of the substrate, with each pixel unit including a light emitting device which includes a first electrode, a light emitting layer and a second electrode in sequence on the side of the substrate; and

an auxiliary electrode layer on a side of the plurality of pixel units distal to the substrate and including light-transmitting regions and electrode regions, with an orthogonal projection of a corresponding light-transmitting region on the substrate at least covering an orthogonal projection of the light emitting layer on the substrate, each light-transmitting region including a transparent structure, each electrode region including an auxiliary electrode, and the auxiliary electrode being electrically connected to the second electrode.

A material of the auxiliary electrodes includes a metal, a material of the transparent structures includes a metal oxide, the metal oxide and the metal have the same kind of element, and the metal oxide is obtained by oxidation of the metal.

In one embodiment, the material of the auxiliary electrodes includes tantalum, and the material of the transparent structures includes a tantalum oxide.

In one embodiment, the tantalum oxide includes at least one of ditantalum trioxide or ditantalum pentoxide.

In one embodiment, a side of the transparent structure proximal to the plurality of pixel units and a side of the auxiliary electrode proximal to the plurality of pixel units are located on a same plane.

In one embodiment, a light shielding layer is disposed between any two adjacent pixel units among the plurality of pixel units, and the auxiliary electrode function as the light shielding layer.

In one embodiment, the display panel further includes: a packaging layer disposed on a side of the auxiliary electrode layer distal to the substrate.

In one embodiment, the auxiliary electrode layer has a shape of a grid including a plurality of meshes distributed in an array and a plurality of grid lines which intersect each other to define the plurality of meshes.

In one embodiment, the transparent structure of each pixel unit is located in one of the plurality of meshes, and an orthogonal projection of each of the plurality of grid lines on the substrate is located outside an orthogonal projection of the transparent structure on the substrate.

In one embodiment, the auxiliary electrodes are in direct contact with the second electrodes.

In one embodiment, the first electrode is an anode and the second electrode is a cathode.

In one embodiment, the first electrode is a reflective electrode.

In a second aspect of the present disclosure, there is provided a manufacturing method of a display panel, including:

forming a substrate;

forming a plurality of pixel units on a side of the substrate, with each pixel unit including a light emitting device which includes a first electrode, a light emitting layer and a second electrode sequentially disposed on the side of the substrate;

forming an auxiliary electrode layer on a side of the plurality of pixel units distal to the substrate, with the auxiliary electrode layer including light-transmitting regions and electrode regions, and an orthogonal projection of a corresponding light-transmitting region on the substrate at least covering an orthogonal projection of the light emitting layer on the substrate; and

forming transparent structures in the light-transmitting regions, forming auxiliary electrodes in the electrode regions, and electrically connecting a corresponding auxiliary electrode to the second electrode.

A material of the auxiliary electrodes includes a metal, a material of the transparent structures includes a metal oxide, the metal oxide and the metal have the same kind of element, and the metal oxide is obtained by oxidation of the metal.

In one embodiment, forming the transparent structures in the light-transmitting regions, forming the auxiliary electrodes in the electrode regions, and electrically connecting the corresponding auxiliary electrode to the second electrode includes:

coating the metal on a side of second electrodes of the plurality of pixel units distal to the substrate;

patterning the metal according to positions of the light-transmitting regions and the electrode regions so as to make the metal include portions corresponding to the light-transmitting regions and portions corresponding to the electrode regions; and

taking the portions of the metal corresponding to the electrode regions as the auxiliary electrodes, and converting the portions of the metal corresponding to the light-transmitting regions to a metal oxide to form the transparent structures.

In one embodiment, patterning the metal according to the positions of the light-transmitting regions and the electrode regions includes:

coating a photoresist on a side of the metal distal to the substrate; and

performing an exposure process and a development process with a mask to left the photoresist merely over cover the portions of the metal corresponding to the electrode regions.

In one embodiment, converting the portions of the metal corresponding to the light-transmitting regions to the metal oxide includes:

performing an oxidation process on the portions of the metal corresponding to the light-transmitting regions with an oxidant.

In one embodiment, the oxidant includes oxydol.

In one embodiment, electrically connecting the corresponding auxiliary electrode to the second electrode includes:

bringing the corresponding auxiliary electrode into direct contact with the second electrode.

In a third aspect of the present disclosure, there is provided a display device, including the display panel of any one of the embodiments in the first aspect of the present disclosure.

### BRIEF DESCRIPTION OF DRAWINGS

FIG. 1 is a schematic structural diagram of a display panel according to the embodiments of the present disclosure (for example, a top view of a plurality of pixel units P of the display panel, which are arranged in an array);

FIG. 2 is a schematic structural diagram of a display panel according to the embodiments of the present disclosure (for example, a top view of an auxiliary electrode layer of the display panel);

FIG. 3 is a sectional view of a display panel according to the embodiments of the present disclosure (for example, a sectional view taken along Line AA′ of FIG. 2);

FIG. 4 is a flowchart illustrating a manufacturing method of a display panel according to the embodiments of the present disclosure;

FIG. 5 is a flowchart of step 3 of FIG. 4; and

FIG. 6 is a schematic diagram illustrating a manufacturing method of a display panel according to the embodiments of the present disclosure.

### DETAIL DESCRIPTION OF EMBODIMENTS

In order to make the objectives, technical solutions and advantages of the present disclosure clearer, the present disclosure will be described in detail below in conjunction with the drawings. Apparently, the embodiments described herein are merely some embodiments of the present disclosure, and do not cover all embodiments. All other embodiments derived by those of ordinary skill in the art from the embodiments described herein without inventive work all fall within the scope of the present disclosure.

The shapes and sizes of the components in the drawings do not necessarily reflect a true scale, and are merely intended to facilitate an understanding of the contents of the embodiments of the present disclosure.

Unless otherwise defined, technical terms or scientific terms used herein should have general meanings that are understood by those of ordinary skill in the technical field to which the present disclosure belongs. The words “first”, “second” and the like used herein do not denote any order, quantity or importance, but are just used for distinguishing between different elements. Similarly, the words “an”, “a”, “the” and the like do not denote a limitation to quantity, and indicate the existence of “at least one” instead. The words “include”, “comprise” and the like indicate that an element or object before the words covers the elements or objects or the equivalents thereof listed after the words, rather than excluding other elements or objects. The words “connect”, “couple” and the like are not limited to physical or mechanical connection, but may also indicate electrical connection, whether direct or indirect connection. The words “on”, “under”, “left”, “right” and the like are only used for indicating relative positional relationships. When an absolute position of an object described is changed, the relative positional relationships may also be changed accordingly.

The inventor of the present disclosure has found that the auxiliary electrodes are generally disposed on a cover plate of the OLED display panel and are disposed opposite to the light emitting devices in the prior art. In such case, the auxiliary electrodes need to be aligned with the cathodes (for example, the auxiliary electrodes need to overlap the cathodes in a direction perpendicular to a substrate 1) and connected to the cathodes, respectively, which causes the problem that the auxiliary electrodes are likely detached from the cathodes or the auxiliary electrodes are not aligned with the cathodes well. In another configuration method, the auxiliary electrodes are generally disposed in a layer of a back plate where gate electrodes or source electrodes are disposed, and are connected to the cathodes of the light emitting devices through a formation process for vias. In such case, the formation process for the vias can easily generate particles regarded as impurities, and the particles can degrade the display quality of the display panel.

In order to solve at least one of the technical problems in the prior art, some embodiments of the present disclosure provide a display panel in which an auxiliary electrode can be directly formed on a second electrode (e.g., a cathode) of a light emitting device, and the auxiliary electrode does not reduce light extraction efficiency of the light emitting device. Thus, the problem that the light extraction efficiency of the light emitting device cannot be improved due to the detachment of the auxiliary electrode from the second electrode or the poor alignment of the auxiliary electrode with the second electrode can be avoided.

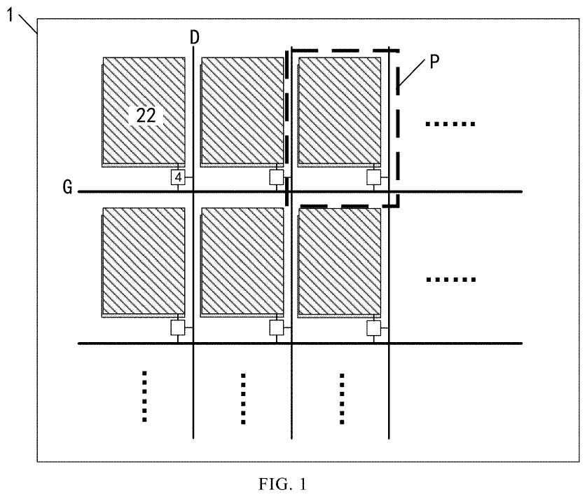

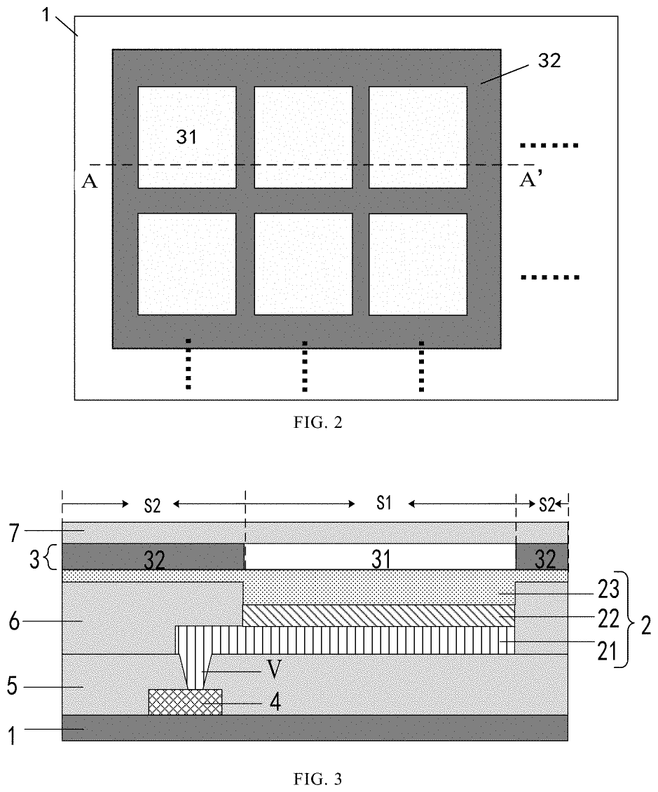

FIG. 1 to FIG. 3 show a display panel according to some embodiments of the present disclosure. For example, FIG. 1 is a top view of light emitting layers and layers below the light emitting layers in the display panel, FIG. 2 is a top view of an auxiliary electrode layer of the display panel, and FIG. 3 is a sectional view of a part (e.g., one pixel unit P) of the display panel taken along Line AA′ of FIG. 2. For example, the display panel may include a substrate 1, a plurality of pixel units P, and an auxiliary electrode layer 3.

For example, the plurality of pixel units P are disposed on a side of the substrate 1, and each pixel unit P includes a light emitting device 2. With reference to FIG. 3, for example, the light emitting device 2 may include a first electrode 21, a light emitting layer 22, and a second electrode 23, which are sequentially disposed on the substrate 1.

It should be noted that the light emitting device 2 in the display panel provided by the embodiments may adopt a top emission structure or a bottom emission structure, which may be designed according to requirements of an actual product. In one embodiment of the present disclosure, the light emitting device 2 adopts a top emission structure, that is, a light-emitting side of the light emitting layer 22 is a side thereof proximal to the second electrode 23. If the light emitting device 2 adopts the top emission structure, the first electrode 21 may be an anode and the second electrode 23 may be a cathode. The description below is given by taking a case where the first electrode 21 serves as the anode and the second electrode 23 serves as the cathode as an example.

Further, with reference to FIG. 1 to FIG. 3, the auxiliary electrode layer 3 may be disposed on a side of the plurality of pixel units P distal to the substrate 1. The auxiliary electrode layer 3 may include light-transmitting regions S1 and electrode regions (which may also be referred to as non-light-transmitting regions) S2, and the light-transmitting regions S1 of the auxiliary electrode layer 3 correspond to positions of the light emitting layers 22 of the light emitting devices 2 (for example, the light-transmitting region S1 partially overlaps or completely overlaps the light emitting layer 22 of each pixel unit P in a direction perpendicular to the substrate 1). That is, for each pixel unit P, an orthogonal projection of the light-transmitting region S1 on the substrate 1 covers (e.g., completely covers) that of the light emitting layer 22 on the substrate 1, and the remaining portion of the auxiliary electrode layer 3 is the electrode region S2, as shown in FIG. 3. For example, the light-transmitting region S1 of the auxiliary electrode layer 3 includes a transparent structure (which may also be referred to as a transparent electrode) 31, the electrode region S2 of the auxiliary electrode layer 3 includes an auxiliary electrode 32, and positions of a plurality of transparent structures 31 in FIG. 2 correspond to the positions of a plurality of light emitting layers 22 in FIG. 1 respectively. In other words, the plurality of transparent structures 31 in FIG. 2 are in one to one correspondence with the plurality of light emitting layers 22 in FIG. 1. Each auxiliary electrode 32 of the auxiliary electrode layer 3 is electrically connected to the second electrode 23 of the corresponding light emitting device 2 (for example, each auxiliary electrode 32 of the auxiliary electrode layer 3 is in direct contact with the second electrode 23 of the corresponding light emitting device 2), so that each auxiliary electrode 32 may reduce an impedance of the corresponding second electrode 23, thereby reducing power consumption of the corresponding light emitting device 2. For example, a material of each auxiliary electrode 32 includes a metal, and a material of each transparent structure 31 includes a metal oxide. For example, the metal oxide of each transparent structure 31 and the metal of each auxiliary electrode 32 have the same kind of element, and the metal oxide of each transparent structure 31 is formed by oxidation of the metal of each auxiliary electrode 32.

It should be noted that an orthogonal projection of each transparent structure 31 (i.e. each light-transmitting region S1) in the auxiliary electrode layer 3 on the substrate 1 covers that of the light emitting layer 22 in the corresponding light emitting device 2 on the substrate 1, that is, an area of each light-transmitting region S1 may be larger than or equal to that of the corresponding light emitting layer 22, so that light emitted by the light emitting layers 22 is kept from being blocked.

In the display panel provided by the embodiments, the auxiliary electrode layer 3 is directly disposed on the second electrodes 23 of the light emitting devices 2, which keeps the auxiliary electrodes 32 from being disposed on a cover plate, and overcomes the problem that the light extraction efficiency of the corresponding light emitting device cannot be improved due to the detachment of the auxiliary electrode 32 from the corresponding second electrode 23 or the poor alignment of the auxiliary electrode 32 with the corresponding second electrode 23. In addition, there is no need to connect each auxiliary electrode 32 to the corresponding second electrode 23 through the formation process for vias. Moreover, for each pixel unit P, since the auxiliary electrode layer 3 includes the light-transmitting region S1 and the electrode region S2, the light emitted by the light emitting layer 22 can be allowed to pass through the position of the light-transmitting region S1 of the auxiliary electrode layer 3, the auxiliary electrode 32 is disposed in the position of the electrode region S2 of the auxiliary electrode layer 3, and is configured to reduce a resistivity of the second electrode 23, so that the light extraction efficiency of the light emitting device 2 is not affected while the resistivity of the second electrode 23 is reduced.

Optionally, in the display panel provided by the embodiments, the material of each auxiliary electrode 32 of the auxiliary electrode layer 3 is a metal, and the material of each transparent structure 31 of the auxiliary electrode layer 3 is a metal oxide formed by oxidation of the metal. Such design can reduce process complexity. Specifically, the material of each auxiliary electrode 32 may include any one of a plurality of metals, for example, the material of each auxiliary electrode 32 may be tantalum (Ta), and the material of each transparent structure 31 includes a tantalum oxide correspondingly. The tantalum oxide has a property of transparency and can allow the light emitted from each light emitting layer 22 to pass therethrough. As an implementation, if the material of each auxiliary electrode 32 is Ta, the material of each transparent structure 31 may be at least one of ditantalum trioxide (Ta₂O₃) or ditantalum pentoxide (Ta₂O₅). Ta₂O₅ has a stable property of corrosion resistance, so that each transparent structure 31 can also protect the corresponding light emitting device 2. Alternatively, the material of each auxiliary electrode 32 may include other metal, and the material of each transparent structure 31 may include other metal oxide as long as the metal oxide have the property of transparency.

Optionally, as shown in FIG. 3, in the auxiliary electrode layer 3, a side of each transparent structure 31 proximal to the plurality of pixel units P and a side of the corresponding auxiliary electrode 32 proximal to the plurality of pixel units P are located on a same plane (i.e., flush with each other). That is, a thickness (e.g., a dimension in the direction perpendicular to the substrate 1) of each transparent structure 31 is the same as that of the corresponding (or adjacent) auxiliary electrode 32. In this way, an upper surface of each transparent structure 31 (i.e., the surface of each transparent structure 31 distal to the plurality of pixel units P) and an upper surface of each auxiliary electrode 32 (i.e., the surface of each auxiliary electrode 32 distal to the plurality of pixel units P) form a flat surface. Thus, the auxiliary electrode layer 3 may also serve as a planarization layer, so as to fill and flatten an upper side of the light emitting devices 2 and protect the light emitting devices 2.

Optionally, as shown in FIG. 2 and FIG. 3, a light shielding layer is disposed among the plurality of pixel units P, and the light shielding layer and each auxiliary electrode 32 in the auxiliary electrode layer 3 are a same structure (i.e., each auxiliary electrode 32 also serves as the light shielding layer). That is, since each auxiliary electrode 32 is made of a metal having a property of opacity and is disposed in a peripheral region of the corresponding light emitting layer 22, on on hand, each auxiliary electrode 32 can be connected to one second electrode 23 to reduce the impedance of the second electrode 23, and on the other hand, and all the auxiliary electrodes 32 can be used as the light shielding layer among the pixel units P to avoid crosstalk of the light emitted from the adjacent pixel units P.

Optionally, as shown in FIG. 3, the display panel provided by the embodiments may further include a packaging layer 7, which is disposed on a side of the auxiliary electrode layer 3 distal to the substrate 1 and configured to package the display panel, so as to prevent moisture from entering an interior of each light emitting device 2 and keep each light emitting device 2 from the damage such caused. The packaging layer 7 may employ various conventional packaging methods, and may include various types of conventional packaging materials, and the packaging method and the packaging material may be selected according to the requirements of the actual product.

Further, as shown in FIG. 1 and FIG. 3, the display panel provided by the embodiments further includes an interlayer insulating layer 5 disposed on a side of the substrate 1 proximal to the packaging layer 7 (or the auxiliary electrode layer 3), and thin film transistors 4 are disposed in the interlayer insulating layer 5. The first electrode (e.g., the anode) 21 of each light emitting device 2 is connected to a thin film transistor 4 (e.g., to a source electrode or a drain electrode of the thin film transistor 4) through a via V (located on the thin film transistor 4, as shown in FIG. 3) provided in the interlayer insulating layer 5. A pixel defining layer (PDL) 6 is further provided on a side of the interlayer insulating layer 5 distal to the substrate 1 and between any two adjacent light emitting devices 2 among the light emitting devices of the plurality of pixel units P. That is, each light emitting device 2 is disposed in the pixel defining layer 6. For example, the thin film transistor 4 may include a plurality of known components, for example, the thin film transistor 4 includes a gate electrode disposed on a side of the substrate 1 proximal to the packaging layer 7; an active layer (or active area) disposed on the gate electrode; a gate insulating layer disposed between the active layer and the gate electrode; a drain electrode and a source electrode disposed on a same layer on a side of the active layer distal to the gate insulating layer; and an interlayer insulating layer disposed between the drain electrode (or source electrode) and the active layer. For example, the active layer is made of a semiconductor material, which may be, for example, amorphous silicon, polycrystalline silicon. an organic semiconductor material, or the like, but the present disclosure is not limited thereto. With reference to FIG. 1, the display panel may further include a plurality of rows of gate lines G extending in a row direction and a plurality of columns of data lines D extending in a column direction, the plurality of rows of gate lines G intersect the plurality of columns of data lines D to define the plurality of pixel units P. Alternatively, a sectional view of each pixel unit P of the display panel may be different from that shown in FIG. 3, for example, the sectional view of each pixel unit P may include three thin film transistors. The sectional view of each pixel unit P may be designed according to the requirements of the actual product, and is not limited herein.

For example, each pixel unit P may include the substrate 1, the thin film transistor 4, the interlayer insulating layer 5, the pixel defining layer 6, and the light emitting device 2 in sequence as shown in FIG. 3.

In some embodiments, the auxiliary electrode layer 3 may have a shape of a grid (as shown in FIG. 2) including a plurality of meshes (i.e., the transparent structures 31 in FIG. 2) distributed in an array and a plurality of grid lines (i.e., strip-like portions of the auxiliary electrodes 32 in horizontal and vertical directions in FIG. 2) which intersect each other to define the plurality of meshes, so that the plurality of meshes overlap the light emitting layers 22 of the plurality of pixel electrodes P respectively in the direction perpendicular to the substrate 1. The transparent structure of each pixel unit P is located in one of the meshes, and an orthogonal projection of each of the plurality of grid lines on the substrate 1 is located outside an orthogonal projection of the transparent structure on the substrate 1, so that the plurality of grid lines do not reduce the light extraction efficiency of each pixel unit P and may avoid the crosstalk of the light emitted by the pixel units P. For each pixel unit P, the auxiliary electrode 32 may be in direct contact with the second electrode 23, thereby reducing the impedance of the second electrode 23 more effectively. For each pixel unit P, the first electrode 21 may be an anode and the second electrode 23 may be a cathode, thereby implementing the top emission structure. For each pixel unit P, the first electrode 21 (e.g., the anode) may be a reflective electrode, for example, a reflectivity of the reflective electrode to the light emitted from the corresponding light emitting layer 22 is greater than or equal to 90%, which may effectively improve a utilization rate of the light emitted from the light emitting layer 22 and improve display brightness of the display panel.

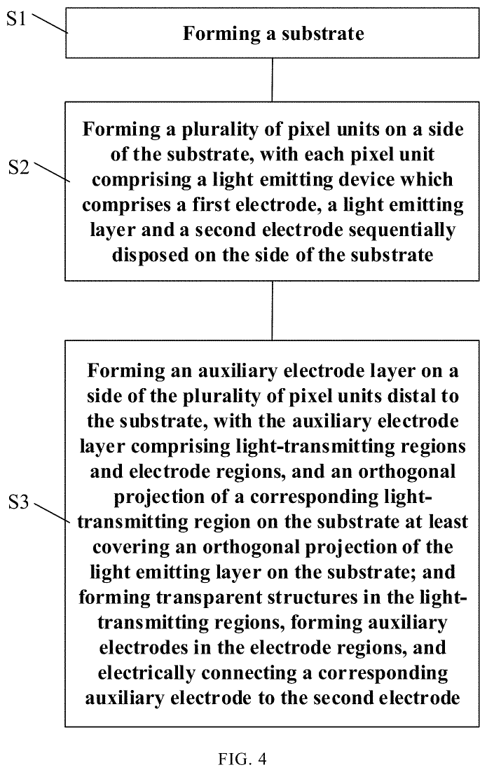

Correspondingly, as shown in FIG. 4, the embodiments further provide a manufacturing method of a display panel (i.e., a method for manufacturing a display panel), and the method may include the following steps S1 to S3.

In the step S1, a substrate 1 is formed.

For example, the substrate 1 may include various types of substrates, such as a glass substrate, a silicon substrate, or the like, but the substrate 1 is not limited thereto.

In the step S2, a plurality of pixel units P are formed on a side of the substrate 1, each pixel unit P includes a light emitting device 2, which includes a first electrode (e.g., an anode) 21, a light emitting layer 22, and a second electrode (e.g., a cathode) 23 sequentially disposed on the side of the substrate 1.

For example, before the first electrode 21 of each pixel unit P is formed, the method may further include sequentially forming a thin film transistor 4 and an interlayer insulating layer 5 on the substrate 1, and forming a via in the interlayer insulating layer 5 to connect the thin film transistor 4 to the first electrode 21. Then, the method may further include forming a pixel defining layer 6 on the interlayer insulating layer 5, with the pixel defining layer 6 exposing the second electrode 23, and printing the light emitting layer 22 in the pixel defining layer 6 and between the first electrode 21 and the second electrode 23 with the inkjet printing technology. Printing materials of light emitting layers 22 may display three colors, namely red (R), green (G) and blue (B), respectively, thereby realizing color display.

In the step S3, an auxiliary electrode layer 3 is formed on a side of the plurality of pixel units P distal to the substrate 1, the auxiliary electrode layer 3 includes light-transmitting regions S1 and electrode regions S2, and an orthogonal projection of the light-transmitting region S1 on the substrate 1 at least covers that of the light emitting layer 22 of the corresponding light emitting device 2 on the substrate 1. For example, the formation of the auxiliary electrode layer 3 may include forming a transparent structure 31 in each light-transmitting region S1, forming an auxiliary electrode 32 in each electrode region S2, and electrically connecting (e.g., bringing into direct contact) the auxiliary electrode 32 to the second electrode 23 of the corresponding light emitting device 2.

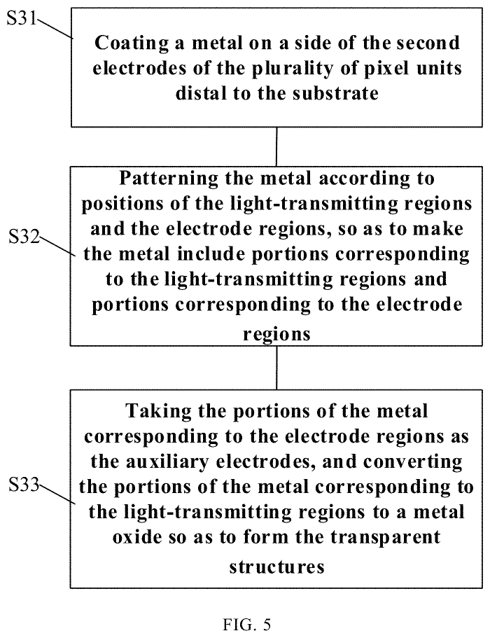

Further, as shown in FIG. 5, the step S3 may include the following steps S31 to S33.

In the step S31, a metal is coated on a side of the second electrodes 23 in the light emitting devices 2 of the plurality of pixel units P distal to the substrate 1.

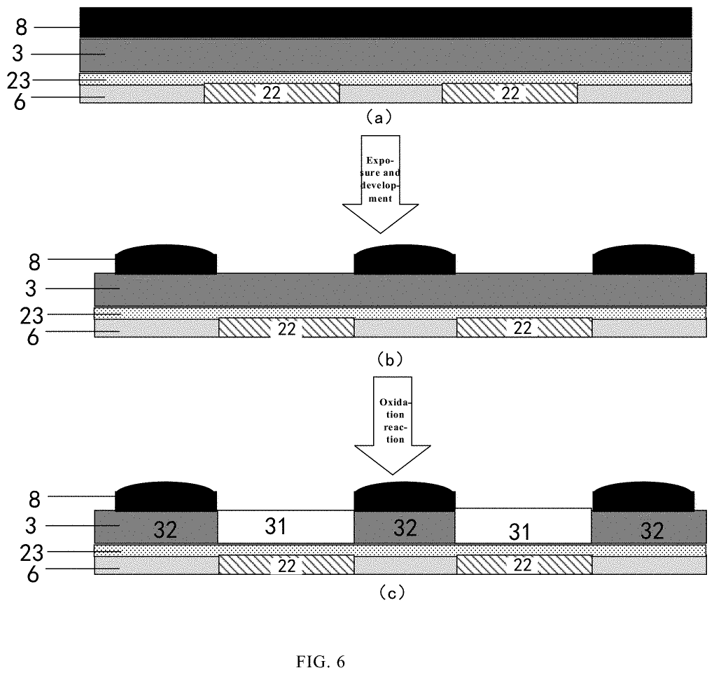

For example, as shown in part (a) of FIG. 6, a layer of the metal (which finally forms the auxiliary electrode layer 3) is coated on the side of each second electrode 23 distal to the substrate 1, and the coated metal is a metal which is made into the auxiliary electrode 32, for example, the coated metal may be Ta.

In the step S32, the coated metal is patterned according to positions of the light-transmitting regions S1 and the electrode regions S2 of the auxiliary electrode layer 3 to be formed, so as to make the metal include portions corresponding to the light-transmitting regions and portions corresponding to the electrode regions.

For example, as shown in the part (a) of FIG. 6, a photoresist 8 is coated on a side of the layer of the metal distal to the substrate 1.

Further, as shown in part (b) of FIG. 6, portions of the photoresist 8 corresponding to the light emitting layers 22 are covered with a mask, with the remaining portions of the photoresist 8 exposed to light. Through an exposure process and a development process, the portions of the photoresist 8 that are not irradiated with the light, that is, the portions of the photoresist 8 corresponding to the light emitting layers 22 (that is, corresponding to the light-transmitting regions S1 or the transparent structures 31) are removed, and the portions of the photoresist 8 that are irradiated with the light, that is, the portions of the photoresist 8 corresponding to the electrode regions S2 or the auxiliary electrodes 32 are kept. That is, the photoresist 8 is left only on the portions of the layer of the metal corresponding to the electrode regions S2 or the auxiliary electrodes 32.

Optionally, the photoresist in the embodiments may be a positive photoresist or a negative photoresist, and the mask used also needs to be changed according to the positive photoresist or the negative photoresist. The positive photoresist is taken as an example in the above description. The positive photoresist or the negative photoresist may be selected as desired, and is not limited herein.

In the step S33, the portions of the layer of the metal corresponding to the light-transmitting regions S1 of the auxiliary electrode layer 3 react with an oxidant to be converted to a metal oxide, so as to form the transparent structures 31, and the portions of the layer of the metal corresponding to the electrode regions S2 of the auxiliary electrode layer 3 serve as the auxiliary electrodes 32.

For example, as shown in part (c) of FIG. 6, the display panel shown in part (b) of FIG. 6 is immersed in the oxidant to perform an oxidation process on the exposed portions of the layer of the metal. Since the portions (i.e., the light-transmitting regions S1 shown in FIG. 3) of the layer of the metal corresponding to the light-transmitting layers 22 are not covered by the photoresist 8, the oxidant reacts with the metal of those portions to oxidize the metal to form a transparent metal oxide, thereby forming the transparent structures 31. Since the remaining portions (i.e., the electrode regions S2 shown in FIG. 3) of the metal are covered by the photoresist 8, the photoresist 8 will protect those portions of the metal from reacting with the oxidant. Therefore, the property of the portions of the layer of the metal corresponding to the electrode regions is not changed, and the metal of those portions may be directly used as the auxiliary electrodes 32 to be connected to the second electrodes 23 of the corresponding light emitting devices 2. In one embodiment, the oxidant is oxydol (i.e., an aqueous solution of hydrogen peroxide), and opaque Ta may be oxidized by oxydol to form a colorless and transparent tantalum oxide (ditantalum trioxide or ditantalum pentoxide).

By manufacturing the auxiliary electrode layer 3 with the above method, the transparent structures 31 and the auxiliary electrodes 32 can be directly formed in different regions of the same layer of the metal by using the photoresist and the oxidant without performing a high-precision process such as an alignment process or a hollow etching process, so that the manufacturing process of the display panel can be simplified, the problems of poor alignment of each auxiliary electrode 32 with the corresponding second electrode 23 and the like can be avoided, and the impedance of the corresponding second electrode 23 can be effectively reduced.

Optionally, the manufacturing method provided by the embodiments may further include forming a packaging layer 7 on a side of the auxiliary electrode layer 3 distal to the substrate 1. For example, the packaging layer 7 may be formed with an evaporation technique or a Chemical Vapor Deposition (CVD) process. For example, a material of the packaging layer 7 may be a known material used for preventing moisture and oxygen from entering interiors of the light emitting devices (e.g., OLEDs).

Correspondingly, the embodiments of the present disclosure further provide a display device, which includes the display panel described above. In addition, the display device may further include a touch panel located on the light-emitting side of the display panel. The display device may be any product or component with a display function, such as a mobile phone, a tablet computer, a television, a display, a notebook computer, a digital photo frame, a navigator, or the like. For the other components of the display device, those of ordinary skill in the art may make a choice according to the requirements of the actual product, and the other components are not described in detail here and should not be taken as limitations to the present disclosure.

It should be understood that the above embodiments are merely exemplary embodiments adopted to illustrate the principle of the present disclosure, and the present disclosure is not limited thereto. Various modifications and improvements can be made by those of ordinary sill in the art without departing from the spirit and essence of the present disclosure defined by the appended claims, and those modifications and improvements should also fall within the scope of the present disclosure.

1. A display panel, comprising:
a substrate;
a plurality of pixel units on a side of the substrate, with each pixel unit comprising a light emitting device which comprises a first electrode, a light emitting layer and a second electrode in sequence on the side of the substrate; and
an auxiliary electrode layer on a side of the plurality of pixel units distal to the substrate and comprising light-transmitting regions and electrode regions, with an orthogonal projection of a corresponding light-transmitting region on the substrate at least covering an orthogonal projection of the light emitting layer on the substrate, each light-transmitting region comprising a transparent structure, each electrode region comprising an auxiliary electrode, and the auxiliary electrode being electrically connected to the second electrode;
wherein a material of the auxiliary electrode comprises a metal, a material of the transparent structure comprises a metal oxide, the metal oxide and the metal have a same kind of element, and the metal oxide is obtained by oxidation of the metal.

2. The display panel of claim 1, wherein the material of the auxiliary electrode comprises tantalum, and the material of the transparent structure comprises a tantalum oxide.

3. The display panel of claim 2, wherein the tantalum oxide comprises at least one of ditantalum trioxide or ditantalum pentoxide.

4. The display panel of claim 1, wherein a side of the transparent structure proximal to the plurality of pixel units and a side of the auxiliary electrode proximal to the plurality of pixel units are on a same plane.

5. The display panel of claim 1, wherein a light shielding layer is between any two adjacent pixel units among the plurality of pixel units, and the auxiliary electrode function as the light shielding layer.

6. The display panel of claim 1, further comprising: a packaging layer on a side of the auxiliary electrode layer distal to the substrate.

7. The display panel of claim 1, wherein the auxiliary electrode layer has a shape of a grid comprising a plurality of meshes distributed in an array and a plurality of grid lines which intersect each other to define the plurality of meshes.

8. The display panel of claim 7, wherein the transparent structure of each pixel unit is located in one of the plurality of meshes, and an orthogonal projection of each of the plurality of grid lines on the substrate is located outside an orthogonal projection of the transparent structure on the substrate.

9. The display panel of claim 1, wherein the auxiliary electrode is in direct contact with the second electrode.

10. The display panel of claim 1, wherein the first electrode is an anode and the second electrode is a cathode.

11. The display panel of claim 1, wherein the first electrode is a reflective electrode.

12. A manufacturing method of a display panel, comprising:
forming a substrate;
forming a plurality of pixel units on a side of the substrate, with each pixel unit comprising a light emitting device which comprises a first electrode, a light emitting layer and a second electrode sequentially disposed on the side of the substrate;
forming an auxiliary electrode layer on a side of the plurality of pixel units distal to the substrate, with the auxiliary electrode layer comprising light-transmitting regions and electrode regions, and an orthogonal projection of a corresponding light-transmitting region on the substrate at least covering an orthogonal projection of the light emitting layer on the substrate; and
forming transparent structures in the light-transmitting regions, forming auxiliary electrodes in the electrode regions, and electrically connecting a corresponding auxiliary electrode to the second electrode;
wherein a material of the auxiliary electrodes comprises a metal, a material of the transparent structures comprises a metal oxide, the metal oxide and the metal have a same kind of element, and the metal oxide is obtained by oxidation of the metal.

13. The manufacturing method of claim 12, wherein forming the transparent structures in the light-transmitting regions, forming the auxiliary electrodes in the electrode regions, and electrically connecting the corresponding auxiliary electrode to the second electrode comprises:
coating the metal on a side of second electrodes of the plurality of pixel units distal to the substrate;
patterning the metal according to positions of the light-transmitting regions and the electrode regions so as to make the metal comprise portions corresponding to the light-transmitting regions and portions corresponding to the electrode regions; and
taking the portions of the metal corresponding to the electrode regions as the auxiliary electrodes, and converting the portions of the metal corresponding to the light-transmitting regions to a metal oxide to form the transparent structures.

14. The manufacturing method of claim 13, wherein patterning the metal according to the positions of the light-transmitting regions and the electrode regions comprises:
coating a photoresist on a side of the metal distal to the substrate; and
performing an exposure process and a development process with a mask to left the photoresist merely over the portions of the metal corresponding to the electrode regions.

15. The manufacturing method of claim 13, wherein converting the portions of the metal corresponding to the light-transmitting regions to the metal oxide comprises:
performing an oxidation process on the portions of the metal corresponding to the light-transmitting regions with an oxidant.

16. The manufacturing method of claim 15, wherein the oxidant comprises oxydol.

17. The manufacturing method of claim 12, wherein electrically connecting the corresponding auxiliary electrode to the second electrode comprises:
bringing the corresponding auxiliary electrode into direct contact with the second electrode.

18. A display device, comprising the display panel of claim 1.

19. The display panel of claim 2, wherein the auxiliary electrode layer has a shape of a grid comprising a plurality of meshes distributed in an array and a plurality of grid lines which intersect each other to define the plurality of meshes.

20. The display panel of claim 3, wherein the auxiliary electrode layer has a shape of a grid comprising a plurality of meshes distributed in an array and a plurality of grid lines which intersect each other to define the plurality of meshes.
